(19) United States
(12) Patent Application Publication
(10) Pub. No.: US 2012/0137185 A1
(43) Pub. Date: May 31, 2012

(54) METHOD AND APPARATUS FOR PERFORMING A MEMORY BUILT-IN SELF-TEST ON A PLURALITY OF MEMORY ELEMENT ARRAYS

(75) Inventors: Ganesh Venkataramanan, Sunnyvale, CA (US); Wei-Yu Chen, Fremont, CA (US)

(73) Assignee: ADVANCED MICRO DEVICES, INC., Sunnyvale, CA (US)

(21) Appl. No.: 12/956,688

(22) Filed: Nov. 30, 2010

(51) Int. Cl. G11C 29/12; G06F 11/27

(52) U.S. Cl. 714/718; 365/201; 714/E11.169

(57) ABSTRACT

A method and apparatus are described for performing a memory built-in self-test (MBIST) on a plurality of memory element arrays. Control packets are output over a first ring bus to respective ones of the arrays. Each of the arrays receives its respective control packet via the first ring bus, and reads commands residing in a plurality of fields within the respective control packet. Each of the arrays performs at least one self-test based on the commands, and outputs a respective result packet over a second ring bus. Each result packet indicates the results of the self-test performed on the array. Each control packet is transmitted in its own individual time slot to a respective one of the arrays.

### FIELD OF INVENTION

The present invention is generally directed to testing semiconductor devices (e.g., integrated circuits (ICs)).

### BACKGROUND

During the manufacture of any product, it is important to test the completed product to ensure that it is satisfactorily operable. When the product is a semiconductor device having relatively complex circuitry, the testing process may be difficult to perform without the inclusion of test circuitry on the device itself. For this purpose, these devices often include on-chip integrated circuits that include the circuitry and processing capability necessary to test the integrity of the device. An example of such a device is a central processing unit (CPU) having a relatively large number of memory element arrays that is designed and manufactured with memory built-in self-test (MBIST) circuitry included on a self-contained CPU chip.

MBIST circuitry typically includes one or more control units that writes data to various memory element arrays on the chip in such a manner that is intended to stress the array. The arrays are then read and the results checked to determine if the data read out from each array is the same as the data written to each array. If the data is not the same, the array is designated as defective.

FIG. 1 is a block diagram of a conventional MBIST interface unit 100, which may reside on a semiconductor device, such as an IC. The MBIST interface unit 100 includes a master control unit 105 and a plurality of functional blocks 1101-110N. Each functional block 110 includes a slave control unit 115 and a plurality of memory element arrays 120, 125, 130 and 135. The master control unit 105 is configured to issue global commands to all of the slave control units 115 via a bus 140 to instruct the slave control units 115 to initiate certain test functions in accordance with an MBIST test algorithm. Responsive to receiving the global commands, the slave control units 115 execute the various test functions in the MBIST test algorithm to test the memory element arrays 120, 125, 130 and 135 they are associated with.

Besides the slave control unit 115 and the memory element arrays 120, 125, 130 and 135, each of the functional blocks 110 may include various other circuit elements needed to carry out particular functions of the semiconductor device, such as an execution unit (EX) and a scheduler (SC). The slave control unit 115 associated with each particular functional block 110 is responsible for testing the integrity of the memory element arrays 120, 125, 130 and 135 associated with that functional block 110.

It should be understood by one of ordinary skill in the art that a semiconductor device may include any number of functional blocks 110, and each functional block 110 may include any number of slave control units 115 and any number of arrays 120, 125, 130 and 135. Furthermore, a semiconductor device may have other functional components that do not include memory element arrays, or have a single functional component that includes memory element arrays. Generally, however, a semiconductor device will include multiple memory arrays of various sizes. For example, in a processor application, each MBIST slave circuit is typically associated with anywhere from five to twenty arrays having memory elements that range in size from 64×32 bits to 256×512 bits. The number of arrays and array sizes may be outside such typical ranges. In the case where a functional block has more than twenty arrays, the arrays may be divided into sets that are each associated with a different MBIST slave circuit.

As shown in FIG. 1, each slave control unit 115 of each functional block 110 is coupled to the arrays 120, 125, 130 and 135 using individual wires 145, 150, 155 and 160. This wiring configuration is referred to as a star configuration. Using the star configuration, the slave control unit 115 may transmit control commands or data to each array 120, 125, 130 and 135 individually. However, while such a configuration may be sufficient when the number of arrays on the semiconductor device is relatively small, for semiconductors, such as CPUs having a large number of arrays, use of individual wires connected between the slave control units 115 and the individual arrays 120, 125, 130 and 135 in the particular functional block 110 is inefficient. This is because a substantial number of wires are included in a small space, causing the semiconductor device to become extremely congested with wires.

FIG. 2 is a block diagram of a conventional MBIST interface unit 200, which may reside on a semiconductor device, such as an IC. The MBIST interface unit 200 includes a master control unit 205 and a plurality of functional blocks 2101-210N. Each functional block 210 includes a slave control unit 215 and a plurality of memory element arrays 220, 225, 230 and 235. The master control unit 205 is configured to issue global commands to all of the slave control units 215 via a bus 240 to instruct the slave control units 215 to initiate certain test functions in accordance with an MBIST test algorithm. Responsive to receiving the global commands, the slave control units 215 execute the various test functions in the MBIST test algorithm to test the memory element arrays 220, 225, 230 and 235 that they are associated with.

As an alternative to the star configuration of the functional blocks 110 of the MBIST interface unit 100 of FIG. 1, the slave control units 215 of the functional blocks 210 of the MBIST interface unit 200 of FIG. 2 are coupled to the arrays 220, 225, 230 and 235 using a ring configuration. In each functional block 210, a ring bus 245 that begins and ends at the slave control unit 215 is utilized. Each of the arrays 220, 225, 230 and 235 is coupled to the ring bus 245 via a wire 250, 255, 260 and 265. Using the ring configuration, the slave control unit 245 may place control commands or data on the ring bus 245. The arrays 220, 225, 230 and 235 each listen to the ring bus 245, identify control commands or data that are intended for them, and read the correct commands/data. Use of such a ring configuration in the functional blocks 210 of FIG. 2 may be more efficient than the star configuration used in the functional blocks 110 of FIG. 1 because it requires less wiring. However, it still requires inclusion of an extra bus and wiring in addition to the ring bus 245 coupled between the master control unit 205 and the slave control units 215.

Due to the large number of arrays included on some semiconductor devices such as CPUs, the MBIST circuitry may become congested with wires connected, for example, between the MBIST control unit and the arrays. These wires occupy valuable space on the IC and increase the cost and complexity of manufacture.

It would be desirable to have available a more efficient semiconductor device configuration that makes use of a bus that is already in place between a master control unit and a plurality of slave control units, for communication between the slave control units and their associated arrays. By using such an efficient semiconductor device configuration, the number of wires included on the semiconductor device may be drastically reduced, thus more efficiently using space on the semiconductor device.

### SUMMARY

A method and apparatus are described for performing a memory built-in self-test (MBIST) on a plurality of memory element arrays. Control packets are output over a first ring bus to respective ones of the arrays. Each of the arrays receives its respective control packet via the first ring bus, and reads commands residing in a plurality of fields within the respective control packet. Each of the arrays performs at least one self-test based on the commands, and outputs a respective result packet over a second ring bus. Each result packet indicates the results of the self-test performed on the array. Each control packet is transmitted in its own individual time slot to a respective one of the arrays.

### BRIEF DESCRIPTION OF THE DRAWINGS

A more detailed understanding may be had from the following description, given by way of example in conjunction with the accompanying drawings wherein:

FIG. 1 is a block diagram of a conventional MBIST interface unit using a star wiring configuration;

FIG. 2 is a block diagram of a conventional MBIST interface unit using a ring bus wiring configuration;

FIG. 3 is a block diagram of a MBIST interface unit that is configured in accordance with the present invention;

FIG. 4 shows the fields of a control packet 400 input into a memory element array for testing and debugging the memory element array; and

FIG. 5 shows the fields of a result packet output by a memory element array in response to receiving the control packet of FIG. 4.

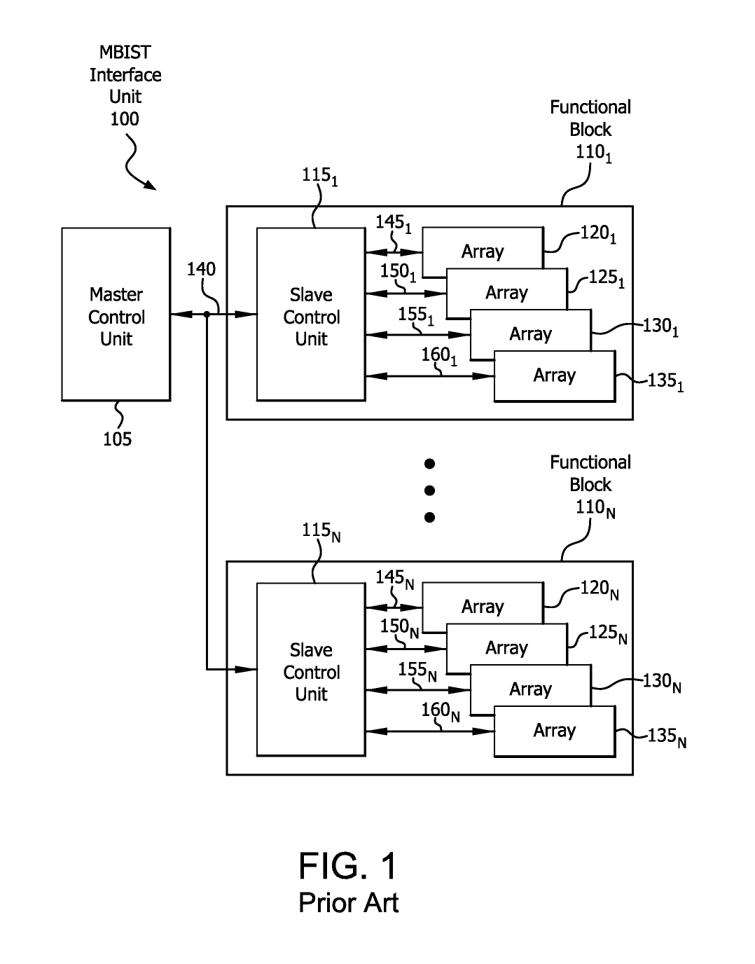

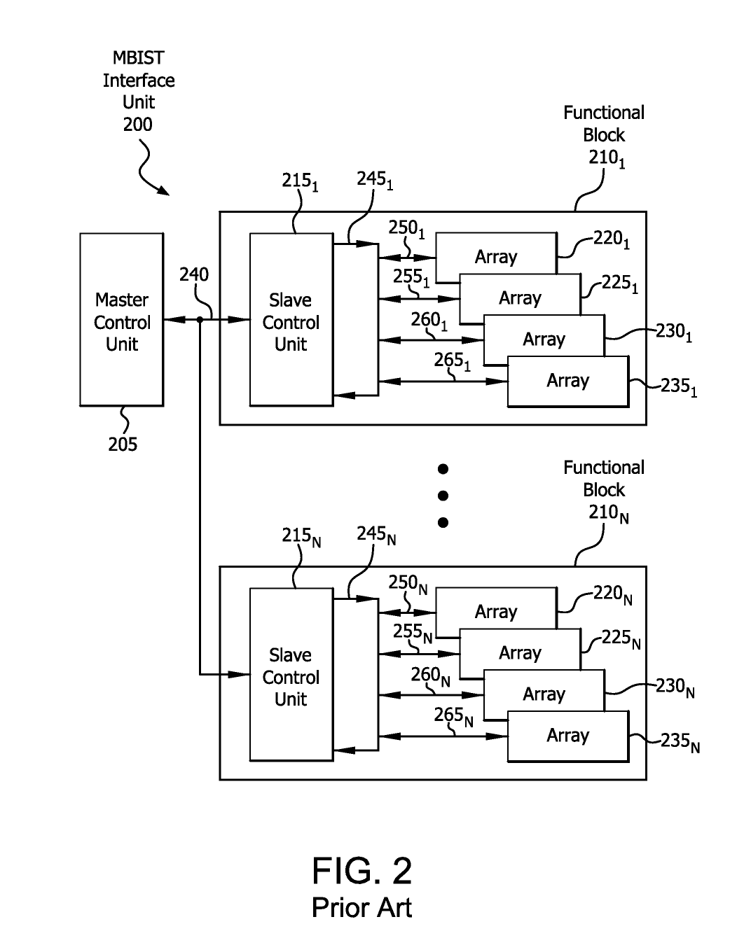

### DETAILED DESCRIPTION

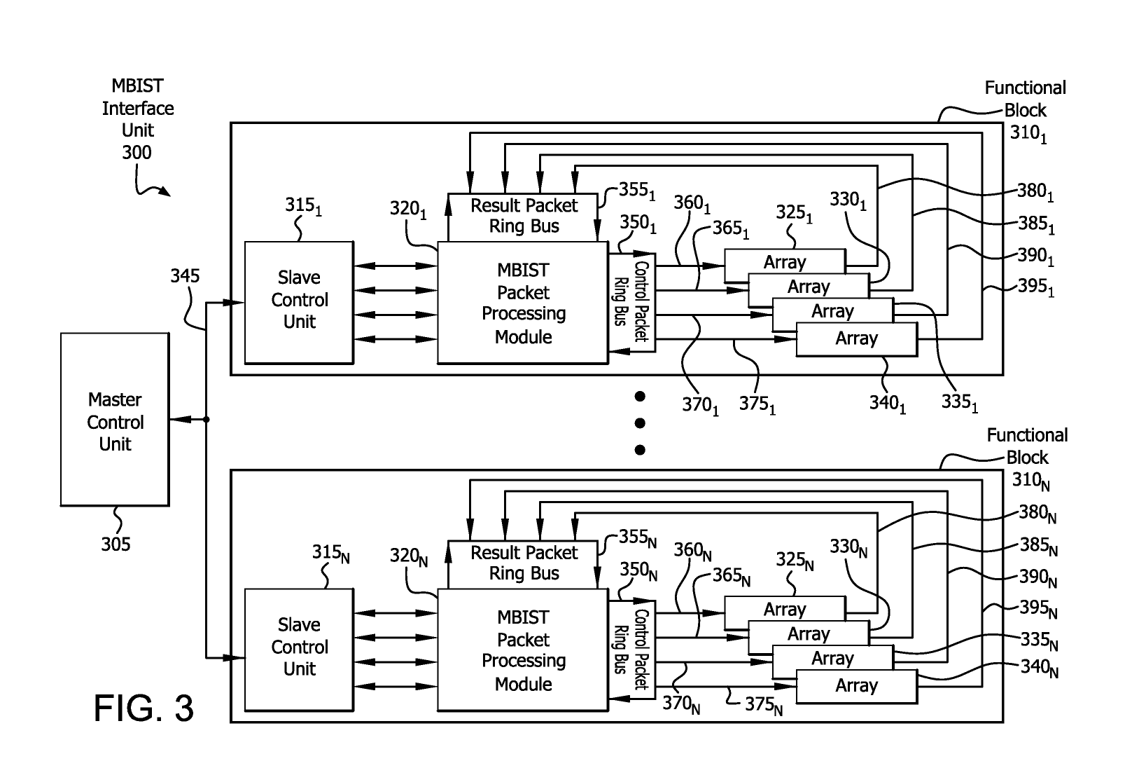

FIG. 3 is a block diagram of a MBIST interface unit 300 that is configured in accordance with the present invention, and which may reside on a semiconductor device, such as a processor, controller, or any IC that includes memory arrays (i.e., units). The MBIST interface unit 300 includes a master control unit 305 and a plurality of functional blocks 3101-110N. Each functional block 310 includes a slave control unit 315, an MBIST packet processing module 320, and a plurality of memory element arrays 325, 330, 335 and 340.

The master control unit 305 is configured to issue global commands to all of the slave control units 315 via a bus 345 to instruct the slave control units 315 to initiate certain test functions in accordance with an MBIST test algorithm. Responsive to receiving the global commands, each of the slave control units 315 send instructions to the respective MBIST packet processing module 320 to execute the various test functions in the MBIST test algorithm to test the memory element arrays 325, 330, 335 and 340 they are associated with.

Besides the slave control unit 315 and the memory element arrays 325, 330, 335 and 340, each of the functional blocks 310 may include various other circuit elements needed to carry out particular functions of the semiconductor device, such as an EX and an SC. The slave control unit 315 associated with each particular functional block 310 is responsible for testing the integrity of the memory element arrays 325, 330, 335 and 340 associated with that particular functional block 310.

It should be understood by one of ordinary skill in the art that a semiconductor device may include any number of functional blocks 310, and each functional block 310 may include any number of slave control units 315, MBIST packet processing modules 320 and arrays 325, 330, 335 and 340. Furthermore, a semiconductor device may have other functional components that do not include memory element arrays, or have a single functional component that includes memory element arrays. Generally, however, a semiconductor device will include multiple memory arrays of various sizes. For example, in a processor application, each MBIST slave circuit is typically associated with anywhere from five to twenty arrays having memory elements that range in size from 64×32 bits to 256×512 bits. The number of arrays and array sizes may be outside such typical ranges. In the case where a functional block has more than twenty arrays, the arrays may be divided into sets that are each associated with a different MBIST slave circuit.

As shown in FIG. 3, each MBIST packet processing module 320 is configured to output control packets to the arrays 325, 330, 335 and 340 via a control packet ring bus 350, and to receive result packets from the arrays 325, 330, 335 and 340 via a result packet ring bus 355. Each control packet is transmitted in its own individual time slot to the inputs 360, 365, 370 and 375 of the respective arrays 325, 330, 335 and 340. The time slots of the control packets are staggered to avoid data collisions.

In response to receiving control packets, the arrays 325, 330, 335 and 340 execute read or write commands by reading or writing data to particular array addresses included in the control packets. In response to receiving a control packet at a particular time slot, each array 325, 330, 335 and 340 reads the control packet and transmits a result packet to the MBIST packet processing module 320 via its respective output 380, 385, 390 and 395.

The MBIST interface unit 300 is configured to set the memory element arrays to a first state for a period of time and to thereafter set each memory element of the arrays to a second state that is the inverse of the first state of the respective memory element for a period of time. After the memory elements are set to the second state, the state of the memory element arrays is read and compared with the data written to the memory element arrays to set them in the second state. In this manner, the MBIST interface unit 300 pre-stresses the arrays 325, 330, 335 and 340 during completion of the manufacturing/testing processes to either force a failure of the semiconductor device or produce a pre-stressed semiconductor device.

The MBIST interface unit 300 may use built-in self-initialization (BISI) to initialize all of the arrays 325, 330, 335 and 340, as well as performing silicon stress for reliability purposes. A generic MBIST test procedure contains a sequence of memory write/read operations such that each array entry is written first. Then, the array entry is read out and compared to the written data to determine whether any errors occurred. The write/read operations may have various combinations to form MBIST test algorithms.

The control commands transmitted by the master control unit 305 and the slave control units 315 are encoded using a protocol that is specific to the control packet ring bus 350. The MBIST packet processing module 320 encodes the commands provided by the master control unit 305. A hierarchical design is used whereby the master control unit 305 communicates to the slave control units 315 with one set of encoding protocols, and the slave control units 315 communicate with the MBIST packet processing module 320 using another set of encoding protocols. Through these two levels of encoding/decoding, the array under test receives the operation that the master control unit 305 wants the array to perform.

The encoding process is necessary because at different times, the master control unit 305 will be sending information/commands to the slave control units 315, and then pass onto the destination array. These information/commands are usually many bits and it is preferred to encode them to save precious routing spaces (silicon area).

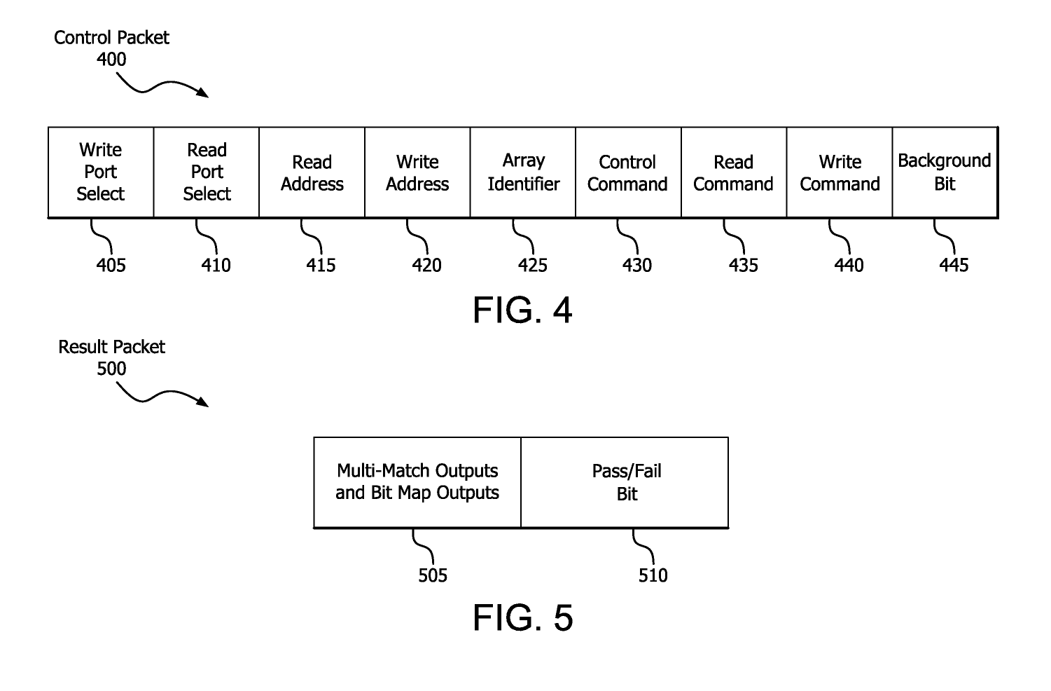

Referring to FIGS. 4 and 5, control packets 400 and result packets 500 are used together for testing and/or debugging. FIG. 4 shows the fields of a control packet 400 input into a memory element array. The control packet 400 tells the array what to do. The arrays respond with the result packet 500 so that the data may be analyzed to determine whether there is an error.

The control packet 400 includes a write port select field 405, a read port select field 410, a read address field 415, a write address field 420, an array identifier field 425, a control command field 430, a read command field 435, a write command field 440 and a background bit field 445.

The write port select field 405 indicates the port bits selected for a write command. The read port select field 410 indicates the port bits selected for a read command. The write port select field 405 is associated with write address field 420, and similarly, the read port select field 410 is associated with read address field 415. For multiple port arrays, it may be desired to further test the arrays in a mode called simultaneous-access, i.e., read and write to the array at the same time but at different entries. This is a normal functional usage and thus is tested in a similar manner.

The read address field 415 indicates the bits that tell the array where to read data from. The write address field 420 indicates the bits that tell the array where to write data to. An array contains many entries. Read/write addresses indicate which entries the data should be read from and written to.

The array identifier field 425 indicates a particular array that is to receive a command. Each array has it own identifier coded locally. When the control packet reaches the array, the identifier is compared. If it matches, the array will perform the command from the control packet 400. If the identifier is not matched, the array will not respond to the control packet 400 since this packet does not belong to this array. By way of example, each array may be assigned a 5-bit identifier that is included with the command. All of the arrays coupled to the control packet ring bus 350 monitor the bus 350 for their unique identifier and, if it is identified, the array reads the command. Otherwise, the array does not read the command on the bus.

The control command field 430 may indicate a background shift enable command (01), a compare enable command (10) to compare results or a bit map enable command (11). There are many MBIST operations including 1) setup the data to be written to the array, 2) compare the array read-out to see if it is expected, and 3) enabling a bitmap function for debugging purposes. These three operations are performed by a MBIST master control unit at different times, and are encoded though the control command field 430 where the background shift enable command corresponds to setup the data to be written to the array, compare enable corresponds to compare the array read-out to see if it is expected, and bitmap enable corresponds to enabling a bitmap function for debugging purposes.

The read command field 435 may indicate a read enable command (01), an inverse read command (10) or a match command (11). The read command field 435 encodes several operations for both random-access memory (RAM) and content-addressable memory (CAM) type of arrays. The read command instructs the array to read out the data and expects it to be the same as what was written to the array. The inverse read command expects the readout to be the inverse of what was written to the array. The match command is used for the CAM array where the comparison is expected to yield a single match in the array, i.e., the array has exactly one entry containing the exact data that was sent for comparison.

The write command field 440 may indicate a write enable command (01), an inverse write enable command (10), or an initialization write command (11). The write command instructs the array to write data into the array, while the inverse-write command will result in inverse data to be written into the array. The ping (i.e., initialization write) command is an indication to the array that currently the slave unit is trying to find out the access latency between the slave control unit and the array. This latency is array dependent and is important to determining the failing address during debugging

The background bit field 445 is a single bit used to serially shift information to be written to the array. For example, if an array has 8 bits per entry, then typically there is an 8-bit register, (i.e., a background register), located in the vicinity of the array that contains the data to be written to the array. The slave unit uses the background bit field 445 to serially populate the 8-bit register (take 8 cycle shifts). Once the register has the 8 bits of data, the array is ready to receive the write command to write these 8 bits into the array. A one bit serial shift mechanism is used to populate the 8-bit register to reduce the number of routing wires.

FIG. 5 shows the fields of a result packet 500 output by a memory element array in response to receiving the control packet 400 of FIG. 4. The result packet 500 includes a field 505 used to represent multi-match outputs and bit map outputs from the arrays. When debugging is performed, the contents of the array need to be determined to see whether they contain all of the bits that are written to. The bit map functionality reads out all of the bits in the array and composes a diagnosis map to determine where a failing bit could be. Similarly, for a CAM array for which it is not possible to read out the array contents, the match output is determined instead to determine whether a multi-match situation exists (versus the correct operation should always yield a single match for CAM BIST operation).

The field 510 includes a pass/fail bit, which indicates whether a particular array is defective or not defective. For example, the pass/fail bit may be a 1 to indicate a defective array, or a 0 to represent a non-defective array (or vice versa). For each entry that is compared to the array read-out, a pass/fail indication occurs. When the slave logic receives this indication, it is passed on to the master control unit 305 where it is logged to indicate that this array under test has been subjected to one or more failures. For example, an array of 10 entries having failures at entry 2 and 5 should have two fail indications when reading out entries 2 and 5, and eight pass indications for the other entries. There is only one bit indication per array to indicate whether the array failed or passed. If a user desires to determine which particular entries of an array failed or passed, a bit map mode must be used to read out the entire array content, which allows one to decide which entry, or bit per entry, is correct and not correct.

Although features and elements are described above in particular combinations, each feature or element can be used alone without the other features and elements or in various combinations with or without other features and elements. The methods or flow charts provided herein may be implemented in a computer program, software, or firmware incorporated in a computer-readable storage medium for execution by a general purpose computer or a processor.

Suitable processors include, by way of example, a general purpose processor, a special purpose processor, a conventional processor, a digital signal processor (DSP), a plurality of processors, one or more processors in association with a DSP core, a controller, a microcontroller, Application Specific Integrated Circuits (ASICs), Field Programmable Gate Arrays (FPGAs) circuits, any other type of integrated circuit (IC), and/or a state machine.

Embodiments of the present invention may be represented as instructions and data stored in a computer-readable storage medium. For example, aspects of the present invention may be implemented using Verilog, which is a hardware description language (HDL). When processed, Verilog data instructions may generate other intermediary data, (e.g., netlists, GDS data, or the like), that may be used to perform a manufacturing process implemented in a semiconductor fabrication facility. The manufacturing process may be adapted to manufacture and test semiconductor devices (e.g., processors) that embody various aspects of the present invention.

What is claimed is:

1. A method of performing a built-in self test on a plurality of units, the method comprising:
transmitting commands to the units over a first ring bus; and
responsive to and based on the transmitted commands, the units outputting results of tests performed on the units over a second ring bus.

2. The method of claim 1 wherein the units are memory element arrays.

3. The method of claim 1 wherein the commands reside in control packets.

4. The method of claim 3 wherein each control packet is transmitted in its own individual time slot to a respective one of the arrays.

5. The method of claim 3 wherein each control packet includes a control command field, a read command field and a write command field.

6. The method of claim 5 wherein the control command field indicates one of a background shift enable command, a compare enable command or a bit map enable command.

7. The method of claim 5 wherein the read command field indicates one of a read enable command, an inverse read command or a match command.

8. The method of claim 5 wherein the write command field indicates one of a write enable command, an inverse write enable command, or an initialization write command.

9. The method of claim 3 wherein each control packet includes a write port select field and a read port select field.

10. The method of claim 9 wherein the write port select field indicates the port bits selected for a write command, and the read port select field indicates the port bits selected for a read command.

11. The method of claim 3 wherein each control packet includes a read address field, a write address field and an array identifier field.

12. A built-in self-test interface device comprising:
a plurality of units;
a first bus over which commands are transmitted to the units; and
a second bus over which results of tests performed on the units are outputted in response to and based on the transmitted commands.

13. The built-in self-test interface device of claim 12 wherein the units are memory element arrays.

14. The built-in self-test interface device of claim 12 wherein the commands reside in control packets.

15. The built-in self-test interface device of claim 14 wherein each control packet is transmitted in its own individual time slot to a respective one of the arrays.

16. The built-in self-test interface device of claim 14 wherein each control packet includes a control command field, a read command field and a write command field.

17. The built-in self-test interface device of claim 14 wherein each control packet includes a write port select field and a read port select field.

18. The built-in self-test interface device of claim 14 wherein each control packet includes a read address field, a write address field and an array identifier field.

19. A computer-readable storage medium configured to store a set of instructions used for testing a semiconductor device, wherein the semiconductor device comprises:
a plurality of units;
a first bus over which commands are transmitted to the units; and
a second bus over which results of tests performed on the units are outputted in response to and based on the transmitted commands.

20. The computer-readable storage medium of claim 19 wherein the instructions are Verilog data instructions.

21. The computer-readable storage medium of claim 19 wherein the instructions are hardware description language (HDL) instructions.
